(19) United States
(12) Patent Application Publication
(10) Pub. No.: US 2025/0151361 A1
(43) Pub. Date: May 8, 2025

(54) METHOD FOR PRODUCING SEMICONDUCTOR DEVICE

(71) Applicant: Sumitomo Electric Device Innovations, Inc., Yokohama-shi (JP)

(72) Inventors: Yukinori NOSE, Yokohama-shi (JP); Kenichi WATANABE, Yokohama-shi (JP)

(73) Assignee: Sumitomo Electric Device Innovations, Inc., Yokohama-shi (JP)

(21) Appl. No.: 19/018,875

(22) Filed: Jan. 13, 2025

Related U.S. Application Data
(62) Division of application No. 17/520,871, filed on Nov. 8, 2021.

(30) Foreign Application Priority Data
Nov. 16, 2020 (JP) 2020-189965

(51) Int. Cl. H10D 64/00; H01L 21/76; H01L 21/765; H10D 30/01; H10D 30/47; H10D 62/824; H10D 62/85

(52) U.S. Cl. CPC H10D 64/111; H01L 21/7605; H01L 21/765; H10D 30/015; H10D 30/475; H10D 62/824; H10D 62/8503

(57) ABSTRACT

A method for producing a semiconductor device includes forming a gate electrode, a source electrode, and a drain electrode on an upper surface of a semiconductor layer, forming a first insulating film on the gate electrode, and forming a field plate on the first insulating film, the field plate having a first metal layer and a second metal layer having a higher Mohs hardness than the first metal layer. The forming the field plate includes forming a resist mask having an opening, the opening exposing a portion of the first insulating film overlapping the gate electrode, forming the first metal layer and the second metal layer in this order on an upper surface of the resist mask and inside the opening, and removing the resist mask and a portion of the first and second metal layers that are disposed on the resist mask by a lift-off process.

### CROSS REFERENCE TO RELATED APPLICATIONS

This application is a Divisional of application Ser. No. 17/520,871, filed Nov. 8, 2021, which contains subject matter related to Japanese Patent Application No. 2020-189965, filed in the Japan Patent Office on Nov. 16, 2020, the entire contents of which are incorporated herein by reference.

### CROSS REFERENCES TO RELATED APPLICATIONS

The present invention contains subject matter related to Japanese Patent Application No. 2020-189965 filed in the Japan Patent Office on Nov. 16, 2020, the entire contents of which are incorporated herein by reference.

### BACKGROUND OF THE INVENTION

### 1. Field of the Invention

The present invention relates to a semiconductor device and a method for producing the semiconductor device.

### 2. Description of the Related Art

In a high-electron-mobility transistor (HEMT), a field plate is disposed above a gate electrode, in some cases (see, for example, Japanese Unexamined Patent Application Publication No. 2010-199241). The field plate can reduce the electric-field concentration to increase the breakdown voltage.

### SUMMARY OF THE INVENTION

The field plate is composed of gold (Au), in some cases. Au is softer than other metals; thus, foreign matter, such as a metal, may adhere to the field plate and may also cause deformation. Accordingly, it is an object of the present disclosure to provide a semiconductor device that can inhibit the adhesion of foreign matter to the field plate and the deformation of the field plate and a method for producing the semiconductor device.

According to one aspect of the present disclosure, a semiconductor device includes a semiconductor layer, a source electrode and a drain electrode that are disposed on the upper surface of the semiconductor layer, a gate electrode disposed on the upper surface of the semiconductor layer and located between the source electrode and the drain electrode, a first insulating film disposed on the gate electrode, and a field plate disposed on the first insulating film, at least part of the field plate overlapping the gate electrode, the field plate including a first metal layer and a second metal layer disposed on the upper surface of the first metal layer, the first metal layer containing gold, the second metal layer containing at least one of tantalum, tungsten, molybdenum, niobium, and titanium.

According to another aspect of the present disclosure, a semiconductor device includes a semiconductor layer, a source electrode and a drain electrode that are disposed on the upper surface of the semiconductor layer, a gate electrode disposed on the upper surface of the semiconductor layer and located between the source electrode and the drain electrode, a first insulating film disposed on the gate electrode, and a field plate disposed on the first insulating film, at least part of the field plate overlapping the gate electrode, the field plate including a first metal layer and a second metal layer disposed on the upper surface of the first metal layer, the second metal layer having a higher Mohs hardness than the first metal layer.

According to another aspect of the present disclosure, a method for producing a semiconductor device includes the steps of forming a gate electrode, a source electrode, and a drain electrode on the upper surface of a semiconductor layer in such a manner that the gate electrode is disposed between the source electrode and the drain electrode, forming a first insulating film on the gate electrode, and forming a field plate on the first insulating film, at least part of the field plate overlapping the gate electrode, the field plate including a first metal layer and a second metal layer disposed on the upper surface of the first metal layer, the first metal layer containing gold, the second metal layer containing at least one of tantalum, tungsten, molybdenum, niobium, and titanium.

### BRIEF DESCRIPTION OF THE DRAWINGS

FIG. 1A is a top view illustrating a semiconductor device according to an embodiment.

FIG. 1B is a cross-sectional view taken along line IB-IB of FIG. 1A.

FIG. 2A is a cross-sectional view illustrating a method for producing a semiconductor device.

FIG. 2B is a cross-sectional view illustrating the method for producing a semiconductor device.

FIG. 2C is a cross-sectional view illustrating the method for producing a semiconductor device.

FIG. 3A is a cross-sectional view illustrating the method for producing a semiconductor device.

FIG. 3B is a cross-sectional view illustrating the method for producing a semiconductor device.

FIG. 3C is a cross-sectional view illustrating the method for producing a semiconductor device.

FIG. 4A is a cross-sectional view illustrating the method for producing a semiconductor device.

FIG. 4B is a cross-sectional view illustrating the method for producing a semiconductor device.

FIG. 4C is a cross-sectional view illustrating the method for producing a semiconductor device.

FIG. 5A is a cross-sectional view illustrating the method for producing a semiconductor device.

FIG. 5B is a cross-sectional view illustrating the method for producing a semiconductor device.

FIG. 6 is a cross-sectional view illustrating a semiconductor device according to a first modification.

FIG. 7 is a cross-sectional view illustrating a semiconductor device according to a second modification.

### DESCRIPTION OF THE PREFERRED EMBODIMENTS

### Description of Embodiments of Present Disclosure

First, embodiments of the present disclosure will be listed and explained.

According to an embodiment of the present disclosure, (1) A semiconductor device includes a semiconductor layer, a source electrode and a drain electrode that are disposed on the upper surface of the semiconductor layer, a gate electrode disposed on the upper surface of the semiconductor layer and located between the source electrode and the drain electrode, a first insulating film disposed on the gate electrode, and a field plate disposed on the first insulating film, at least part of the field plate overlapping the gate electrode, the field plate including a first metal layer and a second metal layer disposed on the upper surface of the first metal layer, the first metal layer containing gold, the second metal layer containing at least one of tantalum, tungsten, molybdenum, niobium, and titanium. The second metal layer is harder than the first metal layer and thus can inhibit the adhesion of foreign matter to the field plate and the deformation of the field plate.

(2) A semiconductor device includes a semiconductor layer, a source electrode and a drain electrode that are disposed on the upper surface of the semiconductor layer, a gate electrode disposed on the upper surface of the semiconductor layer and located between the source electrode and the drain electrode, a first insulating film disposed on the gate electrode, and a field plate disposed on the first insulating film, at least part of the field plate overlapping the gate electrode, the field plate including a first metal layer and a second metal layer disposed on the upper surface of the first metal layer, the second metal layer having a higher Mohs hardness than the first metal layer. The second metal layer is harder than the first metal layer and thus can inhibit the adhesion of foreign matter to the field plate and the deformation of the field plate.

(3) The field plate may include an end portion located between the gate electrode and the drain electrode. In this case, the arrangement of the field plate near the drain electrode to which a high voltage is applied can effectively reduce the electric-field concentration.

(4) The second metal layer may contain an oxide. In this case, the pressure bonding of, for example, a metal fragment to the field plate can be effectively inhibited.

(5) The second metal layer may include an oxide film at least on a surface of the second metal layer. In this case, the pressure bonding of, for example, a metal fragment to the field plate can be effectively inhibited.

(6) The second metal layer may have a thickness of 5 nm or more and 30 nm or less. A thickness of 5 nm or more results in the inhibition of the occurrence of defects in the second metal layer. A thickness of 30 nm or less results in the inhibition of an increase in temperature in the production process.

(7) The semiconductor device may include a second insulating film disposed on the first insulating film and the field plate, the second insulating film including a first opening portion located at a position overlapping the field plate and a second opening portion located at a position overlapping the source electrode, a first via interconnection disposed in the first opening portion, the first via interconnection being in contact with the first metal layer of the field plate, a second via interconnection disposed in the second opening portion, the second via interconnection being electrically coupled to the source electrode, and a lead line electrically coupled to the first via interconnection and the second via interconnection. The first via interconnection is in contact with the first metal layer, thus resulting in improved reliability of the connection between the first via interconnection and the field plate. The source electrode and the field plate are connected to each other through the lead line, the first via interconnection, and the second via interconnection and have the same potential. The field plate having the same potential as the source electrode can effectively reduce the electric field.

(8) A method for producing a semiconductor device includes the steps of forming a gate electrode, a source electrode, and a drain electrode on the upper surface of a semiconductor layer in such a manner that the gate electrode is disposed between the source electrode and the drain electrode, forming a first insulating film on the gate electrode, and forming a field plate on the first insulating film, at least part of the field plate overlapping the gate electrode, the field plate including a first metal layer and a second metal layer disposed on the upper surface of the first metal layer, the first metal layer containing gold, the second metal layer containing at least one of tantalum, tungsten, molybdenum, niobium, and titanium. The second metal layer is harder than the first metal layer and thus can inhibit the adhesion of foreign matter to the field plate and deformation of the field plate.

(9) The step of forming the field plate may include the steps of forming a resist mask on the first insulating film so as to expose a portion of the first insulating film overlapping the gate electrode, forming the first metal layer and the second metal layer on the upper surface of the resist mask and the upper surface of the exposed portion of the first insulating film, and removing the resist mask and a portion of the first metal layer and a portion of the second metal layer that are disposed on the resist mask by a lift-off process. In the lift-off process, metal fragments may scatter. The second metal layer can inhibit the pressure bonding of the metal fragments to the field plate and the deformation of the field plate due to collisions of the metal fragments.

(10) The step of forming the field plate may include a step of successively forming the first metal layer and the second metal layer by a vacuum deposition method.

The second metal layer formed by the vacuum deposition method is oxidized when exposed to air. The formation of an oxide film on the second metal layer effectively inhibits the pressure bonding of metal fragments and so forth.

(11) The method may further include the steps of forming a second insulating film on the first insulating film and the field plate, forming, by etching, a first opening portion in a portion of the second insulating film overlapping the field plate, and a second opening portion in a portion of the first insulating film and a portion of the second insulating film that overlap the source electrode, removing a portion of the second metal layer exposed through the first opening portion by etching, forming a first via interconnection in the first opening portion, the first via interconnection being in contact with the first metal layer of the field plate, forming a second via interconnection in the second opening portion, the second via interconnection being electrically coupled to the source electrode, and forming a lead line electrically connected to the first via interconnection and the second via interconnection. The first via interconnection is in contact with the first metal layer, thus resulting in improved reliability of the connection between the first via interconnection and the field plate. The source electrode and the field plate are connected to each other through the lead line, the first via interconnection, and the second via interconnection and have the same potential. The field plate having the same potential as the source electrode can effectively reduce the electric field.

### Details of Embodiments of Present Disclosure

Specific examples of a semiconductor device according to an embodiment of the present disclosure and a method for producing the semiconductor device will be described below with reference to the attached drawings. The present disclosure is not limited to these embodiments, but is indicated by the appended claims, and is intended to include any modifications within the scope and meaning equivalent to the claims.

### Semiconductor Device

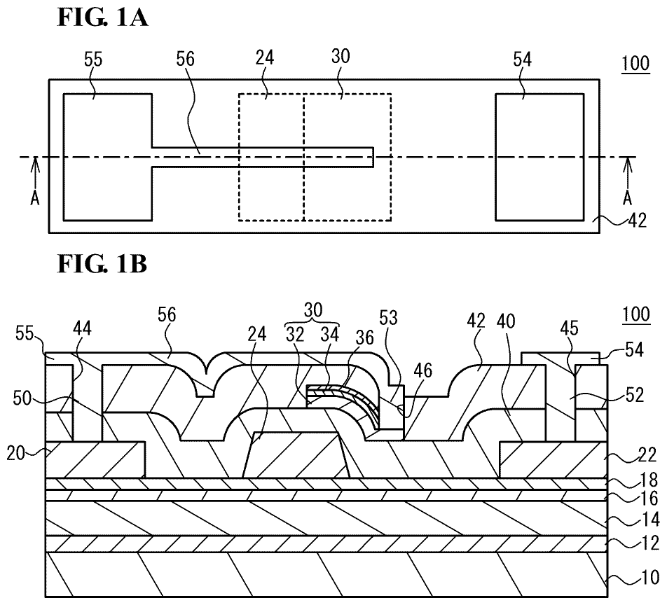

FIG. 1A is a top view illustrating a semiconductor device 100 according to an embodiment. FIG. 1B is a cross-sectional view taken along line IB-IB of FIG. 1A. The semiconductor device 100 illustrated in FIGS. 1A and 1B is a HEMT.

As illustrated in FIG. 1B, the semiconductor device 100 includes a substrate 10, a barrier layer 12, a channel layer 14, an electron supply layer 16, a cap layer 18, a source electrode 20, a drain electrode 22, a gate electrode 24, and a field plate 30.

The barrier layer 12, the channel layer 14, the electron supply layer 16, and the cap layer 18 are stacked, in that order, on the substrate 10. The substrate 10 is composed of, for example, silicon carbide (SiC). The barrier layer 12 is composed of, for example, aluminum nitride (AlN). The channel layer 14 and the cap layer 18 are composed of, for example, gallium nitride (GaN). The electron supply layer 16 is composed of, for example, aluminum gallium nitride (AlGaN) and has a larger band gap than the channel layer 14. In addition to the GaN-based semiconductor materials, these semiconductor layers may also be composed of gallium arsenide (GaAs)-based semiconductor materials.

The source electrode 20, the drain electrode 22, and the gate electrode 24 are disposed on the upper surface of the cap layer 18. The gate electrode 24 is disposed between the source electrode 20 and the drain electrode 22. These three electrodes are separated from each other. Each of the source electrode 20 and the drain electrode 22 is an ohmic electrode formed of, for example, a metal stack, such as a titanium/aluminum (Ti/Al) stack or a tantalum/aluminum (Ta/Al) stack, these metals being stacked in that order from the bottom. The gate electrode 24 is formed of, for example, a metal stack, such as, a titanium/gold (Ti/Au) stack, these metals being stacked in that order from the bottom.

An insulating film 40 (first insulating film) is disposed on the upper surface of the cap layer 18 and covers the side surfaces and the upper surface of each of the source electrode 20, the drain electrode 22, and the gate electrode 24. An insulating film 42 (second insulating film) is disposed on the upper surface of the insulating film 40 and covers the source electrode 20, the drain electrode 22, and the gate electrode 24. The insulating film 40 is an interlayer insulating film composed of, for example, silicon nitride (SiN). The insulating film 42 is an interlayer insulating film composed of, for example, silicon oxide (SiO₂). The insulating film 40 may also be a SiO₂ film. The insulating film 42 may also be a SiN film. Each of the insulating films 40 and 42 has a thickness of, for example, 100 nm or more and 500 nm or less.

The field plate 30 is disposed on the upper surface of the insulating film 40 and located between the insulating films 40 and 42. The field plate 30 is separated from the source electrode 20, the drain electrode 22, and the gate electrode 24 and extends from a position directly above the gate electrode 24 to the outside of the gate electrode 24. One end of the field plate 30 is located between the gate electrode 24 and the drain electrode 22, and the other end is located above the gate electrode 24.

The field plate 30 includes a metal layer 32 (first metal layer) and a metal layer 34 (second metal layer) stacked in that order from the insulating film 40 side. The metal layer 32 includes, for example, a Ti layer and a Au layer stacked in that order from the insulating film 40 side. The Ti layer has a thickness of, for example, 2 nm to 10 nm and functions as a close-contact layer. The Au layer has a thickness of, for example, 100 nm to 500 nm. The metal layer 32 is composed of Au as a main component. The main component refers to a component contained in a concentration of 50 atomic percent or more.

The metal layer 34 is composed of, for example, tantalum (Ta), is in contact with the upper surface of the Au layer of the metal layer 32, and has a higher Mohs hardness than the metal layer 32. For example, Au has a Mohs hardness of 2.5, and Ta has a Mohs hardness of 6.5. The metal layer 34 includes an oxide film 36 on a surface thereof. The oxide film 36 is composed of an oxide of the metal contained in the metal layer 34 and is a film composed of, for example, tantalum oxide. The thickness of the metal layer 34 including the oxide film 36 is smaller than that of the metal layer 32 and is, for example, 5 nm to 30 nm. The metal layer 34 may be composed of a metal selected from, in addition to Ta, tungsten (W), molybdenum (Mo), niobium (Nb), and titanium (Ti), and contains at least one of these metals. The main component of the metal layer 34 is at least one of Ta, W, Mo, Nb, and Ti. For example, Mo has a Mohs hardness of 5.5, Nb has a Mohs hardness of 6.0, and Ti has a Mohs hardness of 6.0. The oxide film 36 is a film formed by oxidation of the metal layer 34 and is composed of an oxide of the above-mentioned metal, for example, tantalum oxide (TaO).

The insulating films 40 and 42 include two opening portions 44 and 45. The insulating film 42 includes an opening portion 46 (first opening portion). The opening portion 44 (second opening portion) is located on the source electrode 20. The opening portion 45 is located on the drain electrode 22. The opening portion 46 is located on the field plate 30. The three opening portions extend in the stacking direction of the layers.

A via interconnection 50 is disposed in the opening portion 44 and electrically coupled to the source electrode 20. A lead line 55 is disposed on the upper surface of the insulating film 42, is coupled to the source electrode 20 through the via interconnection 50, and functions as a source line.

A via interconnection 52 is disposed in the opening portion 45, is electrically coupled to the drain electrode 22. A lead line 54 is disposed on the upper surface of the insulating film 42, is coupled to the drain electrode 22 through the via interconnection 52, and functions as a drain line.

A via interconnection 53 is disposed in the opening portion 46, is in contact with the upper surface of the metal layer 32 of the field plate 30, and thus is electrically coupled to the field plate 30. A lead line 56 is disposed on the upper surface of the insulating film 42, extends from the opening portion 44 to the opening portion 46, and is electrically coupled to the lead line 55 and the via interconnection 53. The source electrode 20 and the field plate 30 are electrically coupled to each other through the via interconnections 50 and 53 and the lead lines 55 and 56. The three via interconnections and the lead lines 54 to 56 are composed of a metal, such as Au, and each include a seed metal layer (not illustrated).

### Production Method

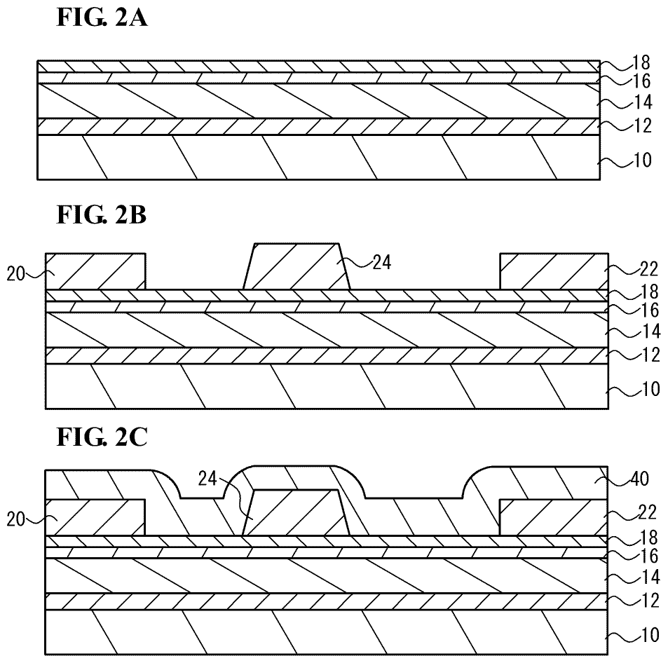

A method for producing the semiconductor device 100 will be described. FIGS. 2A to 5B are cross-sectional views illustrating a method for producing the semiconductor device 100. As illustrated in FIG. 2A, the barrier layer 12, the channel layer 14, the electron supply layer 16, and the cap layer 18 are epitaxially grown, in that order, on the substrate 10 by, for example, a metal-organic chemical vapor deposition (MOCVD) method.

As illustrated in FIG. 2B, the source electrode 20 and the drain electrode 22 are formed on the upper surface of the cap layer 18 by, for example, a vacuum deposition method, and ohmic contacts between the electrodes and the semiconductor layer are formed by heat treatment. Then the gate electrode 24 is formed by the vacuum deposition method.

As illustrated in FIG. 2C, the insulating film 40 composed of SiN is formed on the cap layer 18. The insulating film 40 covers the source electrode 20, the drain electrode 22, and the gate electrode 24. The formation of the insulating film 40 is performed, for example, by a plasma-enhanced chemical vapor deposition (CVD) method, a normal-pressure CVD method, or an atomic layer deposition (ALD) method.

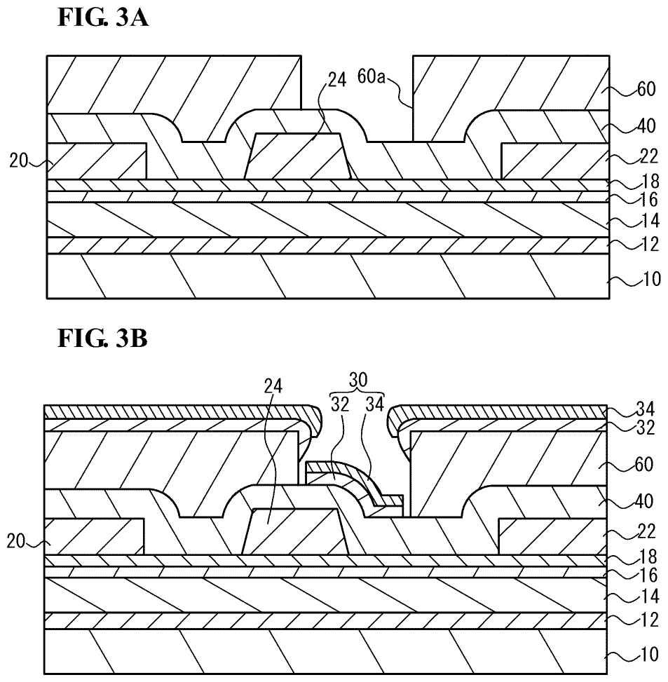

As illustrated in FIG. 3A, a photoresist 60 is applied to the upper surface of the insulating film 40 to a thickness of, for example, 0.5 μm to 2 μm and subjected to patterning by photolithography. An opening portion 60a is formed at a portion of the photoresist 60 overlapping a portion of the gate electrode 24. A portion of the upper surface of the insulating film 40 is exposed through the opening portion 60a.

As illustrated in FIG. 3B, the metal layer 32 composed of Au and the metal layer 34 composed of Ta are sequentially formed, for example, by a vacuum deposition method. The formation of the metal layer 32 and the formation of the metal layer 34 are successively performed, so that the metal layer 34 is disposed on a surface of the metal layer 32. The field plate 30 is disposed on the upper surface of the insulating film 40, and the metal layer 32 and the metal layer 34 are also disposed on the upper surface of the photoresist 60. The substrate 10 is removed from a vapor deposition apparatus and exposed to air, thereby oxidizing the metal layer 34.

As illustrated in FIG. 3C, the photoresist 60 and the metal layers 32 and 34 on the photoresist 60 are removed by a lift-off process. Specifically, for example, a chemical solution containing an organic solvent, such as N-methylpyrrolidone (NMP), is sprayed toward the photoresist 60 through a nozzle 62 to remove the photoresist 60 from the cap layer 18.

In the lift-off process, the metal layers 32 and 34 on the photoresist 60 break into metal fragments 64 having a length of, for example, 1 μm or less and scatter around. For example, in the case where the field plate does not include the metal layer 34, the metal layer 32 is exposed. The metal layer 32 is a Au layer, which is soft and whose surface is resistant to oxidation. The metal fragments 64 may be pressure-bonded to the metal layer 32. The metal layer 32 may also be deformed by collisions of the metal fragments 64. When the field plate 30 is subjected to pressure bonding of the metal fragments 64, deformation, and so forth, the insulating film 42 is subjected to deformation, cracking, and so forth. This may cause, for example, a short circuit between the field plate 30 and other electrodes, decreasing the breakdown voltage.

As illustrated in FIG. 3C, the field plate 30 according to this embodiment includes the metal layer 34 on a surface thereof. The metal layer 34 is composed of, for example, Ta and has a higher Mohs hardness than the metal layer 32 composed of Au. The metal layer 34 is easily oxidized and includes the oxide film 36 on a surface thereof. The metal fragments 64 are not easily pressure-bonded to the hard and oxidized surface of the metal layer 34, and deformation and so forth due to collisions of the metal fragments 64 are inhibited.

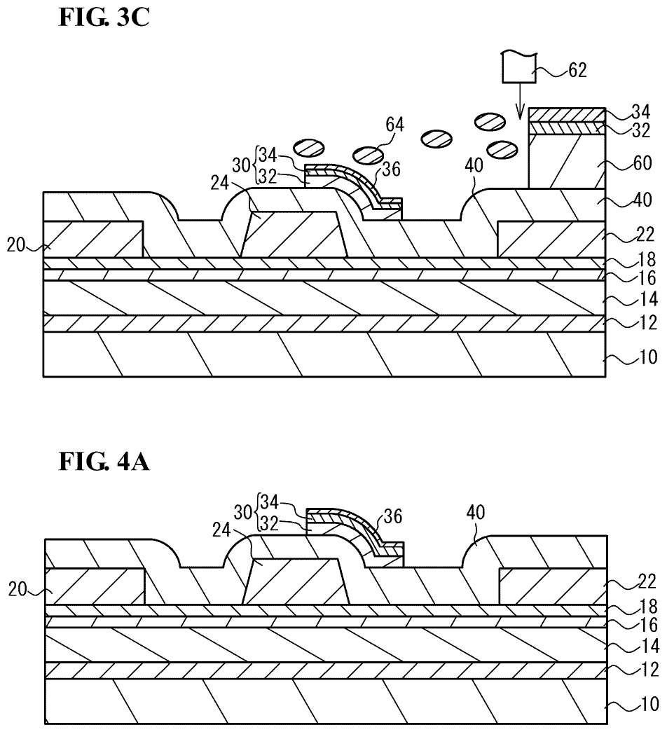

As illustrated in FIG. 4A, the photoresist 60 is removed by the lift-off process, leaving the field plate 30 without the metal fragments 64 adhering thereto.

As illustrated in FIG. 4B, the insulating film 42 is formed by, for example, a plasma-enhanced CVD method on the upper surface of the insulating film 40.

As illustrated in FIG. 4C, a photoresist 65 is applied to the upper surface of the insulating film 42 to a thickness of 0.5 μm to 2 μm and subjected to patterning. Three opening portions are formed by the patterning in the layer of the photoresist 65. After the patterning of the photoresist, dry etching is performed with a fluorinated gas, such as sulfur hexafluoride (SF₆), carbon tetrafluoride (CF₄), or trifluoromethane (CHF₃) or a chlorinated gas, such as chlorine (Cl₂), silicon tetrachloride (SiCl₄), or boron trichloride (BCl₃).

The insulating films 40 and 42 are dry-etched to form the opening portions 44 and 45. The source electrode 20 is exposed through the opening portion 44. The drain electrode 22 is exposed through the opening portion 45. The insulating film 42 is dry-etched to form the opening portion 46. When the opening portion 46 is formed, a portion of the metal layer 34 overlapping the opening portion 46 is also etched. The metal layer 32 of the field plate 30 is exposed through the opening portion 46. After the etching, the photoresist 65 is removed.

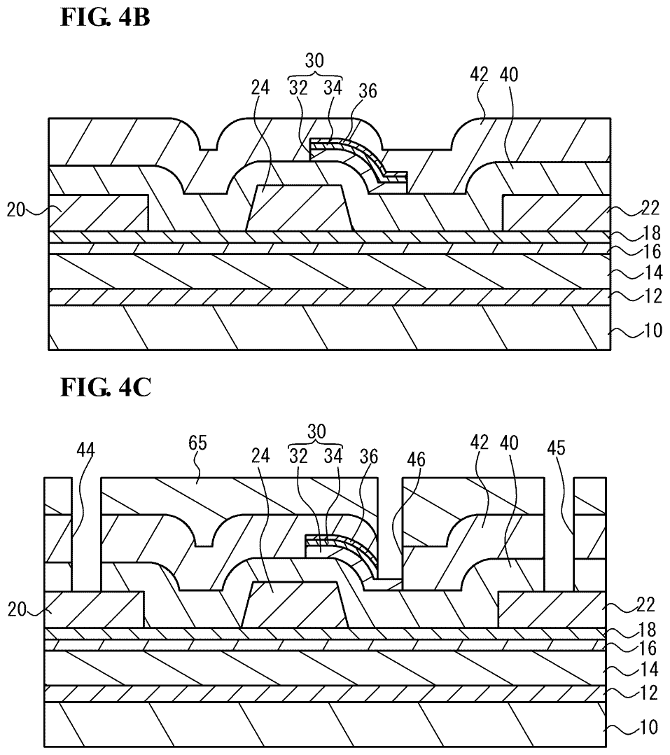

As illustrated in FIG. 5A, a seed metal 66 is formed on a surface of the insulating film 42. The seed metal 66 covers the upper surface of the insulating film 42 and the inner walls and the bottoms of the opening portions 44 to 46. The seed metal 66 includes a Ti layer and a Au layer sequentially stacked. The Ti layer functions as a close-contact layer.

As illustrated in FIG. 5B, an electroplating process is performed while a current is passed through the seed metal 66, thereby forming the via interconnections 50, 52, and 53 and the lead lines 54 to 56. After the plating process, an unnecessary portion of the seed metal 66 is removed. Portions of the seed metal 66 are left below the via interconnections 50, 52, and 53 and the lead lines 54 to 56. The semiconductor device 100 is produced by the above process.

According to this embodiment, the field plate 30 is disposed on a portion of the upper surface of the insulating film 40 overlapping the gate electrode 24. The field plate 30 includes the metal layers 32 and 34. For example, the metal layer 34 is a Ta layer harder than the metal layer 32 composed of Au. Specifically, the Mohs hardness of the metal layer 34 is higher than that of the metal layer 32. The presence of the metal layer 34 can inhibit the adhesion of foreign matter to the field plate 30 and can also inhibit the deformation of the field plate 30 due to collisions of the foreign matter. This inhibits deformation, cracking, and so forth of the insulating film 42, so that short-circuits between the field plate 30 and other electrodes are less likely to occur. Accordingly, the semiconductor device 100 has an improved breakdown voltage.

Specifically, in the lift-off process illustrated in FIG. 3C, the metal layers 32 and 34 on the photoresist 60 break into the metal fragments 64 and scatter. When the metal layer 32 composed of Au is exposed, the metal fragments 64 may be pressure-bonded to the metal layer 32. In processes other than the lift-off process, metal or non-metal foreign matter may adhere during, for example, a cleaning process and conveyance. According to the embodiment, the metal layer 34 covers the metal layer 32. This can inhibit the adhesion of foreign matter, such as the metal fragments 64, and can also inhibit the deformation and so forth of the field plate 30 due to collisions of the metal fragments 64.

The metal layer 34 contains at least one of Ta, W, Mo, Nb, and Ti. The metal layer 34 containing the at least one metal has a higher Mohs hardness than the metal layer 32 composed of Au and thus can effectively inhibit the pressure bonding of foreign matter, for example. When a fluorinated gas is used in the dry etching illustrated in FIG. 4C, the metal layer 34 reacts with the gas to form a fluoride of the metal. The fluorides of the above-mentioned metals have a boiling point of 300° C. or lower and vaporize. When a chlorinated gas is used in the dry etching, a chloride of the metal layer 34 vaporizes. Accordingly, the metal layer 34 can be easily removed by the dry etching.

As illustrated in FIG. 1B, one end portion of the field plate 30 is located between the gate electrode 24 and the drain electrode 22. The field plate 30 including the metal layer 34 and inhibiting the pressure bonding of the metal fragments 64 is disposed near the drain electrode 22 to which a high voltage is applied. This can effectively reduce the electric-field concentration.

The metal layer 34 preferably includes the oxide film 36 at least on a surface thereof. The metal fragments 64 and so forth are less likely to be pressure bonded to the oxide film 36, compared with a non-oxidized surface. The material, such as Ta, of the metal layer 34 is easily oxidized. The metal layer 34 covers the surface of the metal layer 32 by successive formation of the metal layers 32 and 34 by the vacuum deposition method. The metal layer 34 exposed at the surface is exposed to air to form the oxide film 36.

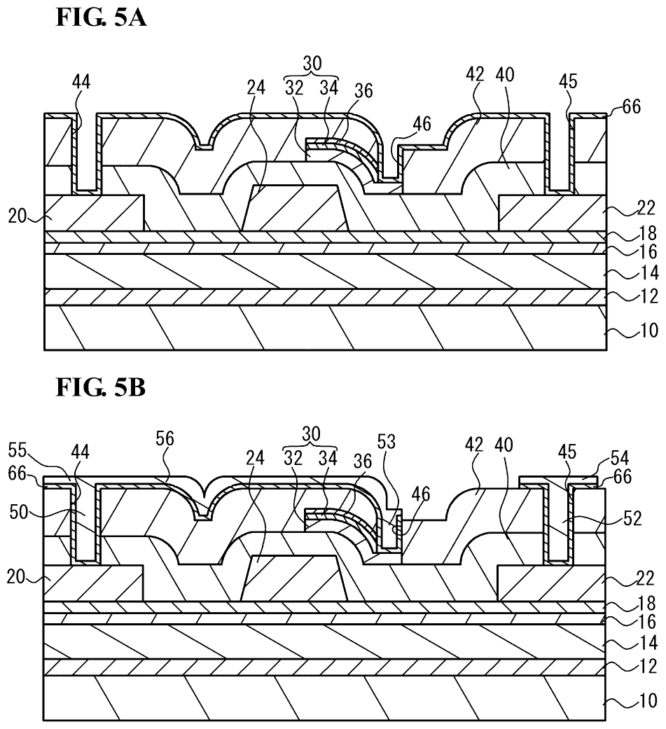

FIG. 6 is a cross-sectional view illustrating a semiconductor device 110 according to a first modification. The entire metal layer 34 is oxidized, not just the surface. That is, the metal layer 34 is the oxide film 36 composed of an oxide of, for example, Ta. The rest of the structure is the same as in the embodiment illustrated in FIG. 1B. As illustrated in FIGS. 1B and 6, it is sufficient that at least the surface of the metal layer 34 is oxidized. This can effectively inhibit the pressure bonding of the metal fragments 64 and so forth to the field plate 30. As described above, the whole or part of the metal layer 34 may be oxidized. For example, at least half of the metal layer 34 may be composed of an oxide, or 90% or more of the metal layer 34 may be composed of an oxide. As illustrated in FIG. 1A, the metal layer 34 preferably includes the oxide film 36 at least on the surface thereof.

When the metal layer 34 is thin, the metal layer 34 may be a discontinuous layer with defects, possibly exposing the metal layer 32. When the metal layer 34 is thick, the temperature of the field plate 30 may increase in, for example, the vacuum deposition process, possibly deforming the photoresist 60. To cover the metal layer 32 and to control the temperature increase, the metal layer 34 preferably has a thickness of 5 nm or more and 30 nm or less. The lower limit of the thickness may be, for example, 10 nm or more or 15 nm or more. The upper limit of the thickness may be, for example, 40 nm or less or 50 nm or less. The thickness of the metal layer 34 includes the thickness of the oxide film 36.

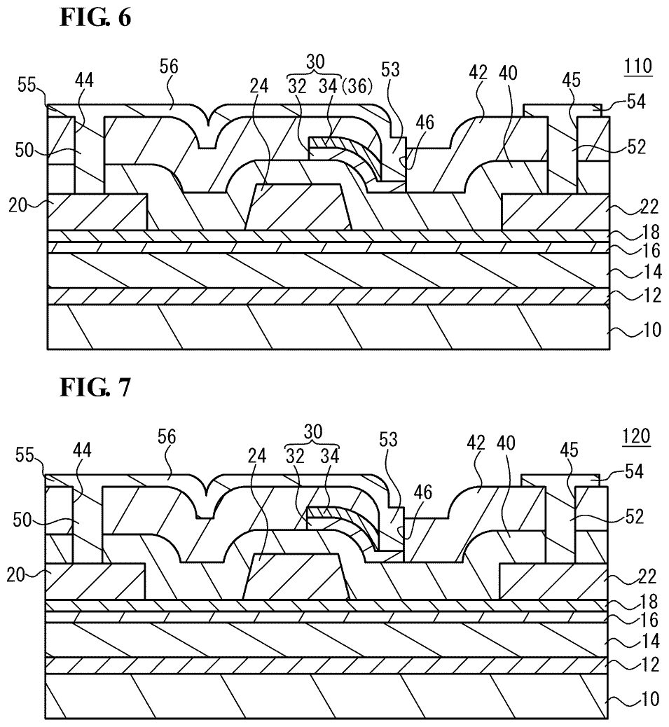

FIG. 7 is a cross-sectional view illustrating a semiconductor device 120 according to a second modification. The metal layer 34 does not include the oxide film 36. The rest of the structure is the same as in the embodiment illustrated in FIG. 1B. As illustrated in FIG. 7, the surface of the metal layer 34 is not oxidized. After the formation of the metal layer 34, the metal layer 34 is not exposed to air, and the insulating film 42 is then formed. For example, after the formation of the metal layer 34, the metal layer 34 is stored in a nitrogen atmosphere; thus, the insulating film 42 can be formed while oxidation is inhibited. Alternatively, the insulating film 42 may be successively formed after the step of forming the metal layer 34 without exposing the metal layer 34 to air. The metal layer 34 can be formed without forming the oxide film 36 on the surface of the metal layer 34, and then the metal layer 34 can be covered with the insulating film 42. After the formation of the insulating film 42, the same steps as in the embodiment can be performed to form the semiconductor device 120. According to the second modification, it is possible to effectively inhibit the pressure bonding of the metal fragments 64 and so forth to the field plate 30.

The etching illustrated in FIG. 4C removes a portion of the metal layer 34 of the field plate 30 and the oxide film 36 together with the metal layer 34, thereby exposing the metal layer 32. As illustrated in FIG. 1B, the via interconnection 53 is in contact with the metal layer 32 to lead to the improved strength of the connection with the field plate 30. The metal layer 34 having a thickness of, for example, several nanometers may be left on the etched portion of the field plate 30, and the via interconnection 53 may be connected to the metal layer 34. For a stable connection with the via interconnection 53, at least the oxide film 36 is preferably removed by etching. The source electrode 20 and the field plate 30 are electrically coupled to each other through the via interconnections 50 and 53 and the lead line 56. The field plate 30 and the source electrode 20 can have the same potential. The field plate 30 with the same potential as the source electrode 20 can effectively reduce the electric field.

The via interconnections 50, 52, and 53 and the lead line 56 are, for example, layers of Au plating. Three via interconnections and the lead line 56 can be formed by a single plating process, thus simplifying the production process. The via interconnections 50 and 53 and the lead lines 56 are the same Au layer, thus resulting in higher reliability of the connection.

While the embodiments of the present disclosure have been described in detail above, the present disclosure is not limited to these specific embodiments. Various modifications and changes can be made within the scope of the invention as defined in the appended claims.

What is claimed is:

1. A method for producing a semiconductor device, comprising the steps of:
forming a gate electrode, a source electrode, and a drain electrode on an upper surface of a semiconductor layer in such a manner that the gate electrode is disposed between the source electrode and the drain electrode;
forming a first insulating film on the gate electrode; and
forming a field plate on the first insulating film, at least part of the field plate overlapping the gate electrode, the field plate including a first metal layer and a second metal layer disposed on an upper surface of the first metal layer, the second metal layer having Mohs hardness equal to or higher than the first metal layer,
wherein the forming the field plate includes the steps of:
forming a resist mask on the first insulating film having an opening, the opening exposing a portion of the first insulating film overlapping the gate electrode;
forming the first metal layer and the second metal layer in this order on an upper surface of the resist mask and inside the opening; and
removing the resist mask and a portion of the first and second metal layers that are disposed on the resist mask by a lift-off process.

2. The method according to claim 1, wherein the step of forming the field plate includes a step of successively forming the first metal layer and the second metal layer by a vacuum deposition method.

3. The method according to claim 1, further comprising the steps of:
forming a second insulating film on the first insulating film and the field plate;
forming, by etching, a first opening portion in a portion of the second insulating film overlapping the field plate, and a second opening portion in a portion of the first insulating film and a portion of the second insulating film that overlap the source electrode;
removing a portion of the second metal layer exposed through the first opening portion by etching;
forming a first via interconnection in the first opening portion, the first via interconnection being in contact with the first metal layer of the field plate;
forming a second via interconnection in the second opening portion, the second via interconnection being electrically coupled to the source electrode; and
forming a lead line electrically connected to the first via interconnection and the second via interconnection.

4. The method according to claim 1, wherein the second metal layer contains at least one of tantalum, tungsten, molybdenum, niobium, and titanium.
